(19) United States
(12) Patent Application Publication
(10) Pub. No.: US 2023/0340686 A1
(43) Pub. Date: Oct. 26, 2023

(54) ELECTROHYDRODYNAMIC EJECTION PRINTING AND ELECTROPLATING FOR PHOTORESIST-FREE FORMATION OF METAL FEATURES

(71) Applicant: Lam Research Corporation, Fremont, CA (US)

(72) Inventors: Steven T. Mayer, Aurora, OR (US); Kari Thorkelsson, Portland, OR (US)

(21) Appl. No.: 17/759,673

(22) PCT Filed: Jan. 27, 2021
(86) PCT No.: PCT/US2021/015247

§ 371 Date: Jul. 28, 2022

Related U.S. Application Data
(60) Provisional application No. 62/969,368, filed on Feb. 3, 2020.

(51) Int. Cl. C25D 7/12; H01L 21/768; C25D 5/48; H01L 23/00; C25D 5/10; C25D 5/02; C25D 21/12; H01L 21/288; C25D 3/38

(52) U.S. Cl. CPC C25D 7/123; C25D 3/38; C25D 5/02; C25D 5/10; C25D 5/48; C25D 21/12; H01L 21/2885; H01L 21/76885; H01L 24/03; H01L 24/05; H01L 24/11; H01L 24/13; H01L 24/742; H01L 2224/03318; H01L 2224/03464; H01L 2224/03614; H01L 2224/03912; H01L 2224/05073; H01L 2224/05166; H01L 2224/05181; H01L 2224/05184; H01L 2224/05573; H01L 2224/05582; H01L 2224/05647; H01L 2224/05655; H01L 2224/11462; H01L 2224/13147; H01L 2224/13582; H01L 2224/13655; H01L 2224/742; H01L 2924/0132

(57) ABSTRACT

Methods, inks, apparatus, and systems for forming metal features on semiconductor substrates are provided herein. Advantageously, the techniques herein do not require the use of photoresist, and can be accomplished without many of the processes and apparatuses used in the conventional process flow. Instead, electrohydrodynamic ejection printing is used to deposit an ink that includes an electroplating additive such as accelerator or inhibitor. The printed substrate can then be electroplated in a preferential deposition process that achieves a first deposition rate on areas of the substrate where the ink is present and a second deposition rate on areas of the substrate where the ink is absent, the first and second deposition rates being different from one another. After electroplating, chemical etching may be used to spatially isolate the preferentially grown metal features from one another.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Fabrication of semiconductor devices commonly involves a series of steps for forming fine line interconnects or other metallic features. Such features may be formed over the course of several processing steps involving many different pieces of semiconductor processing equipment. For example, in the area of 3D packaging, metallization may involve forming a conductive seed layer on the substrate, forming a layer of photoresist on the seed layer, exposing and developing the layer of photoresist to define a pattern therein, descumming the substrate to remove any remaining undesired photoresist within the patterned features, plating the substrate with metal, stripping the photoresist, and chemical etching to remove any exposed seed layer that was previously protected by photoresist.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, systems, inks, and electroplating electrolytes for electrohydrodynamic ejection printing and electroplating. The techniques described herein enable photoresist-free formation of metal features, substantially simplifying the process scheme for forming such features and minimizing the associated capital and processing costs. Generally, the techniques herein utilize particular inks that include one or more electroplating additives such as a plating accelerator or plating inhibitor. The ink is selectively printed on the substrate in a desired pattern, and the additives react with the substrate surface to become strongly adsorbed to the surface. After the ink dries, the substrate is electroplated, and the strongly adsorbed electroplating additive from the printed ink stays adsorbed on the surface where it was printed, and causes a preferential plating process that provides differential plating rates at printed vs. non-printed areas of the substrate. The differential plating rates result in the formation of metal features. After plating, the features can be electrically and spatially isolated from one another by etching.

In one aspect of the disclosed embodiments, a method of depositing metal on a substrate is provided, the method including: (a) receiving a substrate including a seed layer, where the seed layer is conductive and is exposed on a surface of the substrate; (b) printing an ink in a pattern on the seed layer through electrohydrodynamic ejection printing, where the ink includes an electroplating additive dissolved in a solvent, where the electroplating additive includes an accelerator or an inhibitor, and where the electroplating additive strongly adsorbs onto the seed layer; and (c) electroplating metal on the substrate through a preferential deposition that provides a first deposition rate at locations where the electroplating additive from the ink is present and a second deposition rate at locations where the electroplating additive from the ink is absent, where the first deposition rate is different from the second deposition rate.

In some embodiments, the electroplating additive includes an accelerator, and the first deposition rate is greater than the second deposition rate such that the metal is preferentially deposited at locations where the accelerator from the ink is present. In these or other cases, the accelerator may include an alkane chain with at least one mercapto- and one sulfonic acid group, or an acid-salt. For instance, the accelerator may include mercaptopropane sulfonic acid or mercaptoethane sulphonic acid. In these or other cases, the solvent in the ink may include at least one material selected from the group consisting of: water, terpineol, ethylene carbonate, propylene carbonate, dimethylsulfoxide (DMSO), ethylene glycol, and propylene glycol.

The method may further include chemically etching the substrate to remove a portion of the metal deposited in (c) and a portion of the seed layer, thereby forming metal features at locations where the accelerator from the ink is present, the metal features being spatially isolated from one another. In some such cases, the substrate is electroplated in (c) in an electrolyte including: between about 10-1000 ppm plating suppressor additive, between about 10-60 g/L copper ions, between about 5-180 g_{/}L acid, and between about 30-80 ppm halide ions. In such embodiments, accelerator in the electrolyte (if present) will tend to increase the plating rate in areas where the accelerator from the ink is not present (e.g., unprinted areas), and will tend to reduce the contrast in deposition rate between the printed and non-printed areas. Therefore, in various embodiments, the electrolyte may be either free of accelerator or have only trace amounts of accelerator.

In some embodiments, the electroplating additive includes an inhibitor. In such embodiments, the first deposition rate is lower than the second deposition rate such that the metal is preferentially deposited at locations where the inhibitor from the ink is absent

In certain embodiments, the method may further include chemically etching the substrate to remove a portion of the metal deposited in (c), the ink printed in (b), and a portion of the seed layer, thereby forming metal features at locations where the inhibitor from the ink was absent, the metal features being spatially isolated from one another. In some cases using an inhibitor ink, the substrate may be electroplated in (c) in electrolyte including: between about 0-1000 ppm accelerator, between about 10-60 g/L copper ions, and between about 5-180 g/L. acid. In various embodiments, the electrolyte may be either free of the inhibitor or have only a trace amount of the inhibitor. In some such cases, the electrolyte may also be free of a plating suppressor additive, or have only a trace amount of the plating suppressor additive.

In some embodiments, the substrate further includes an adhesion barrier layer positioned under the seed layer. The method may further include: (d) chemically etching the substrate to remove a portion of the metal deposited in (c) and a portion of the seed layer, thereby forming metal features, the metal features being spatially isolated from one another; and (e) electroplating a second metal onto the substrate, wherein the second metal selectively deposits on the metal features formed in (d), without substantially forming on the adhesion barrier layer. In some such cases, the second metal may form a diffusion barrier layer. The method may further include (f) electroplating solder material onto the diffusion barrier layer, where the solder material selectively deposits on the diffusion barrier layer formed in (e), without substantially forming on the adhesion barrier layer. In various embodiments, the electroplating additive in the ink reacts with and chemically binds to the seed layer on the substrate.

In another aspect of the disclosed embodiments, an electrohydrodynamic ejection printing apparatus is provided, including a controller configured to cause any one or more of the electrohydrodynamic printing steps claimed or otherwise described herein.

In some embodiments, the electrohydrodynamic ejection printing apparatus may include a nozzle with a tip, the tip having an opening that has a diameter between about 50-5000 nm, an ink reservoir fluidically connected with the nozzle, a substrate support for supporting a substrate during printing, and a power supply configured to apply a potential between the nozzle and the substrate support or between the nozzle and the substrate.

In another aspect of the disclosed embodiments, an electroplating apparatus is provided, including a controller configured to cause any one or more of the electroplating steps claimed or otherwise described herein.

In some embodiments, the electroplating apparatus includes a chamber for holding electrolyte, a substrate holder configured to hold a substrate during electroplating, an anode, and a power supply configured to apply potential between the anode and the substrate during electroplating.

In another aspect of the disclosed embodiments, a system for processing a substrate is provided, the system including: an electrohydrodynamic ejection printing apparatus; an electroplating apparatus; and a controller configured to cause any one or more of the steps claimed or otherwise described herein.

In a further aspect of the disclosed embodiments, a system for processing a substrate is provided, the system including: an electrohydrodynamic ejection printing apparatus including: a nozzle having an opening that has a diameter between about 50-5000 nm, an ink reservoir fluidically connected with the nozzle, a substrate support for supporting the substrate during printing, and a power supply configured to apply a potential between the nozzle and the substrate support or between the nozzle and the substrate; an electroplating apparatus including: a chamber for holding electrolyte, a substrate holder configured to hold the substrate during electroplating, an anode, and a power supply configured to apply potential between the anode and the substrate during electroplating; and a controller configured to cause: printing ink in a pattern on the substrate using the electrohydrodynamic ejection printing apparatus, where the ink includes an electroplating additive dissolved in a solvent, the electroplating additive including an accelerator or an inhibitor, and after printing the ink on the substrate, electroplating metal on the substrate using the electroplating apparatus, where the electroplating occurs through a preferential deposition that provides a first deposition rate at locations where the electroplating additive from the ink is present and a second deposition rate at locations where the electroplating additive from the ink is absent, and where the first deposition rate is different from the second deposition rate.

In various embodiments, the system may further include an apparatus configured to deposit a seed layer on the substrate. In certain implementations, the system may further include a physical vapor deposition apparatus configured to deposit a seed layer on the substrate. In certain implementations, the system further includes an electroless plating module configured to deposit a seed layer on the substrate. In certain embodiments the system further includes an electroless plating activation module. In these or other embodiments, the controller may be configured to cause depositing the seed layer on the substrate before the ink is printed on the substrate.

In some implementations, the system further includes a chemical etching apparatus configured to remove metal from the substrate. In these or other embodiments, the controller may be configured to cause removing a portion of the metal electroplated onto the substrate and removing a portion of the seed layer on the substrate. In some implementations, the electrohydrodynamic ejection printing apparatus and the electroplating apparatus may be provided together in a single tool.

In a further aspect of the disclosed embodiments, an ink for electrohydrodynamic ejection printing is provided, the ink including: a solvent including at least one material selected from the group consisting of: water, terpineol, ethylene carbonate, propylene carbonate, dimethylsulfoxide (DMSO), ethylene glycol, and propylene glycol; and an electroplating additive dissolved in the solvent, where the electroplating additive includes an accelerator or an inhibitor, and where the electroplating additive is present in the solvent at a concentration between about 0.1-10 g/L.

In another aspect of the disclosed embodiments, an ink for electrohydrodynamic ejection printing is provided, the ink including: an electroplating additive including an accelerator or an inhibitor, where the electroplating additive is present at a concentration between about 0.1-10 g/L; and a solvent having: a vapor pressure when at 25° C. that is equal to or less than about 24 Torr, and a dielectric constant between about 40-90, where the ink has a viscosity between about 0.7-20 cP, and where the electroplating additive is completely dissolved in the solvent.

In some embodiments, a concentration of oxygen in the ink is about 1 ppm or less. Oxygen may react with certain ink additives over time and thereby reduce the necessary concentration of the ink’s critical electrochemically active compound. In some embodiments, the ink contains an additional species that can react with and consume oxygen. The species that can react with and consume oxygen may be present at a concentration sufficient to maintain a concentration of oxygen in the ink at about 1 ppm or less. This may improve the shelf-life of the ink. In some embodiments, the species that can react with and consume oxygen is a sulfite compound. One particular example is sodium sulfite. In some implementations, electroplating additive in the ink includes the accelerator. In some other implementations, the electroplating additive in the ink includes the inhibitor. In a number of embodiments, the solvent may include at least one material selected from the group consisting of: water, terpineol, ethylene carbonate, propylene carbonate, dimethylsulfoxide (DMSO), ethylene glycol, and propylene glycol. In some embodiments, the solvent is organic. In these or other embodiments, the solvent may have a natural boiling point between about 95-275° C. al In these or other embodiments, the solvent may include a first co-solvent and a second co-solvent. In these or other cases, the solvent may include a wetting agent. The wetting agent reduces the contact angle between the ink and the seed layer. The wetting agent may prevent discontinuous or drop-wise printing. In these or other cases, the ink may include a salt.

These and other aspects are described further below with reference to the drawings.

### BRIEF DESCRIPTION OF THE DRAWINGS

FIG. 1A is a flowchart describing a method of forming metal features using photoresist-based techniques.

FIG. 1B depicts the various pieces of processing equipment used to carry out the method of FIG. 1A.

FIG. 2A is a flowchart describing a method of forming metal features according to an embodiment herein.

FIG. 2B illustrates the processing equipment used to carry out the method of FIG. 2A.

FIGS. 3A-3D depict a partially fabricated semiconductor substrate as it undergoes the method of FIG. 2A utilizing an accelerator ink in an electrohydrodynamic ejection printing process.

FIGS. 4A-4D depict a partially fabricated semiconductor substrate as it undergoes the method of FIG. 2A utilizing an inhibitor ink in an electrohydrodynamic ejection printing process.

FIG. 5 illustrates a close-up view of a nozzle and substrate during an electrohydrodynamic ejection printing process according to certain embodiments.

FIG. 6 depicts an electroplating cell according to certain implementations.

FIG. 7 illustrates an electroplating tool having multiple electroplating cells and other features according to certain embodiments.

FIG. 8 shows an electroplating tool having multiple electroplating cells and other features according to certain embodiments.

FIGS. 9A-9D illustrate a partially fabricated semiconductor substrate as it undergoes formation of a multi-film stack according to certain embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

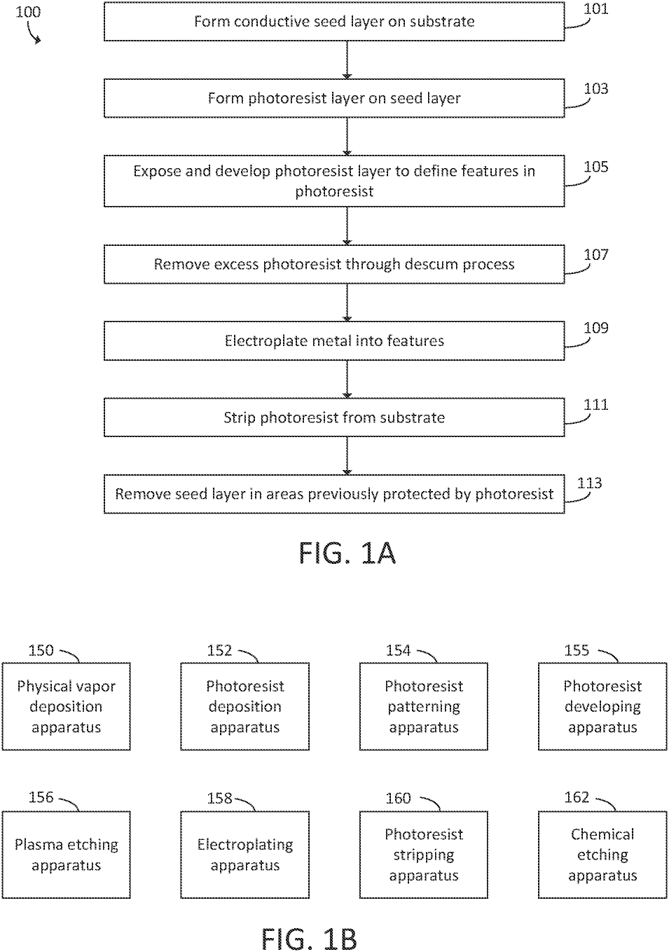

FIG. 1A is a flowchart describing a series of steps for forming a fine line interconnect, pad, or other metal feature on a substrate according to conventional methods. FIG. 1B depicts the various pieces of semiconductor processing equipment used to carry out the method 100 described in FIG. 1A. The steps shown in FIG. 1A will be described in the context of the apparatuses shown in FIG. 1B

In FIG. 1A, the method 100 begins with operation 101, where a conductive seed layer is deposited on a substrate. This deposition occurs in a physical vapor deposition apparatus 150 shown in FIG. 1B. Next, the substrate is transferred to a photoresist deposition apparatus 152, and in operation 103 a layer of photoresist is formed on the seed layer. The photoresist may be formed through wet processing methods such as spin coating, or it may be formed through dry methods such as applying a roll of pre-formed photoresist material over the substrate, for example.

After the photoresist layer is formed, the substrate is transferred to a photoresist patterning apparatus 154, where the photoresist layer is patterned through exposure to particular light conditions in operation 105. Also in operation 105, the substrate is transferred to a photoresist developing apparatus 155, where the pattern exposed on the substrate is developed. In one example, the photoresist is developed through a wet chemical treatment that involves exposing the substrate to a solution having a dissolution salt therein, such as a solution of potassium carbonate in water. Together, these patterning operations result in formation of recessed features in the photoresist layer. These recessed features define the spaces where metal will later be deposited.

Next, the substrate is transferred to a plasma etching apparatus 156, and at operation 107 a descumming process takes place to remove excess photoresist material from the bottoms of the features. The descumming process typically involves exposure to an oxygen-containing plasma that acts to burn off excess photoresist at the bottom of the features.

The substrate is then transferred to an electroplating apparatus 158, and at operation 109 metal is plated (e.g., through electroplating or electroless plating) into the features defined in the photoresist layer. The substrate is then transferred to a photoresist stripping apparatus 160, and in operation 111 the photoresist layer is stripped from the substrate. The photoresist may be stripped through dry plasma etching techniques (e.g., by exposing the substrate to oxygen-containing plasma) or through wet techniques (e.g., by exposing the substrate to photoresist solvents to dissolve or swell the photoresist film, after which the photoresist may be removed with high flow, ultrasonic energy, or other methods). After the photoresist layer is removed, the substrate is transferred to a chemical etching apparatus 162, and in operation 113 the seed layer is removed in areas that were previously protected by the photoresist layer.

In many cases, each of the apparatuses shown in FIG. 1B are distinct apparatuses, each configured to perform a particular operation in the process flow described in FIG. 1A. Together, FIGS. 1A and 1B illustrate that the conventional process flow for forming metalized features such as fine line interconnects is complex, time consuming, and expensive. Many different specialized semiconductor processing apparatuses are required, and each must be appropriately configured for a particular application. The large number of steps and apparatuses involved with the conventional process flow make it difficult to make any changes or adjustments to substrate processing techniques (including, e.g., substrate design and layout), since every process and piece of equipment must be appropriately adjusted. This makes it difficult to switch between production of one substrate type or substrate design to another. Similarly, it is difficult to run tests, make prototype substrates, etc., due to the complex process flow and large number of apparatuses involved.

The techniques described herein allow for formation of fine line interconnects, pads, and other similar metallized features, without the need for many of the processes and apparatuses described in FIGS. 1A and 1B. As a result, the fabrication process is significantly simplified, the number of processing apparatuses is substantially reduced, and the cost associated with processing is similarly reduced (e.g., because fewer steps are involved, and because a substantial portion of the processing cost is directly related to the capital expense of acquiring the processing apparatuses) .

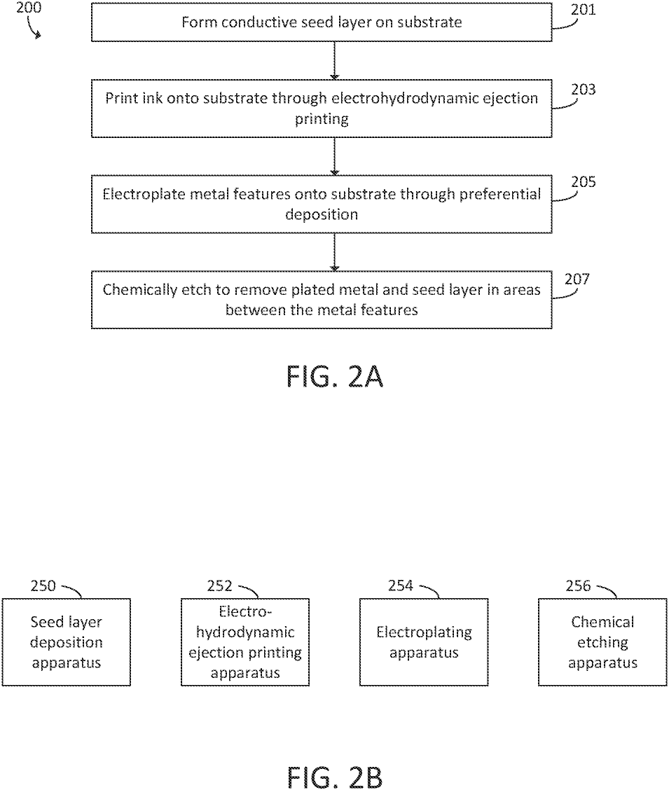

FIG. 2A is a flowchart describing a method of forming a fine line interconnect or similar metallized feature according to an embodiment herein. FIG. 2B depicts the processing equipment used to carry out the method 200 of FIG. 2A. The steps shown in FIG. 2A will be described in the context of the apparatuses shown in FIG. 2B.

In FIG. 2A, the method 200 begins at operation 201, where a conductive seed layer is formed on a substrate in seed layer deposition apparatus 250. In some cases, the seed layer may be formed through physical vapor deposition in a physical vapor deposition apparatus. As is known in the art, the seed layer may also be formed by other methods such as electroless plating. In some embodiments, electroless plating starts with an electroless activation step (which may involve, e.g., exposing the substrate to stannic ions), followed by tin(II) to tin(IV) displacement/activation with a palladium ion-containing electrolyte. This leaves the substrate surface with palladium electrocatalyst thereon, and allows for the metallization of many dielectric materials. In some cases, electroless plating may occur via a solution containing a reducing agent and metal ions of the metal desired to be plated as the seed layer. Examples of suitable reducing agents for use in creating a seed layer of copper include dimethylamine borane (DMAB) and potassium hypophosphate.

In various embodiments, the substrate may be optionally pre-treated after the seed layer is formed in operation 201 and before electrohydrodynamic ejection printing in operation 203. This pre-treatment may be performed to remove surface oxides on the seed layer. The pre-treatment may occur through wet methods or dry methods. For example, wet methods may involve applying a dilute acid such as H₂SO₄ or a reducing agent such as dimethylamine borane (DMAB) to the substrate. Dry methods may involve heating the substrate to a temperature of about 100-200° C. in a reducing atmosphere such as forming gas. Such pre-treatment may be particularly beneficial in embodiments where the substrate is exposed to atmospheric conditions (or other oxygen-containing environment) after deposition of the seed layer in operation 201 and prior to electrohydrodynamic ejection printing in operation 203.

Whatever the particular method used in forming and optionally pre-treating the seed layer, the substrate is provided to an electrohydrodynamic ejection printing apparatus 252, and in operation 203, ink is selectively printed onto the substrate through electrohydrodynamic ejection printing. The ink is an electrochemically active ink as described further below. Other methods of depositing the ink onto the substrate can be used, but electrohydrodynamic ejection printing is particularly suitable for applications where a very high resolution liquid transference is required, specifically for semiconductor interconnect and packaging applications, where the lines, spaces and structures are generally smaller than about 50 µm, more commonly less than 10 or even less than 2 µm in critical dimension.

Selective deposition of electrochemically active ink using an electrohydrodynamic ejection printing process also involves the development of inks with suitable properties for storage, transport, delivery to the substrate surface, and solubility of active chemical ingredients such as appropriate solvents and activating chemicals to work with this process. In various embodiments herein, the ink includes one or more plating additive dissolved in a solvent. Example plating additives include accelerators and inhibitors, discussed further below. Appropriate solvents and other species that may be present in the ink are also discussed further below.

After the ink has dried on the substrate surface, the plating additive and any other non-volatile materials in the ink remain on the substrate surface. At this point, the substrate may be optionally rinsed, for example with deionized water. While not wanting to be held to any particular model or theory, to remain where printed, functionally useful plating additives according to embodiments herein are believed to be most effective if they react chemically with the substrate metal seed layer and become strongly attached and immobilized at the surface. In other words, the plating additive may react with and chemically bind to the seed layer on the substrate. As a class, thiol end group (e.g., R-S-H end groups) mercapto-compounds are one example of materials that will bind to a copper seed layer (and some other metal seed layers or other surfaces) and exhibit desired immobilization characteristics. Specific examples of compounds of this class include mercapto-propane sulphonic acid (e.g., which may act as an accelerator) and mercaptohexanol (e.g., which may act as an inhibitor). Another example class of strongly metal-binding compounds are triazoles. Benzotriazole is an example of a useful triazole that may act as an inhibitor. Benzotriazole-5-sulphonic acid and benzotriazole-5-carboxylic acid are examples of triazoles that may act as accelerators. After rinsing, the substrate may be subjected to spin drying or another drying method to remove any undesired materials. The rinsing may remove some or all of the non-volatile materials originating from the ink, excluding the plating additive. Much or all of the plating additive should remain on the substrate surface after the optional rinsing, for example as a result of the immobilization described above.

Next, the substrate is transferred to an electroplating apparatus 254, and in operation 205, metal is electroplated on the substrate to form features through preferential deposition. The deposition process is preferential because the ink includes at least one plating additive that either promotes (e.g., accelerator) or retards (e.g., inhibitor)plating relative to areas where the ink/plating additive is absent.

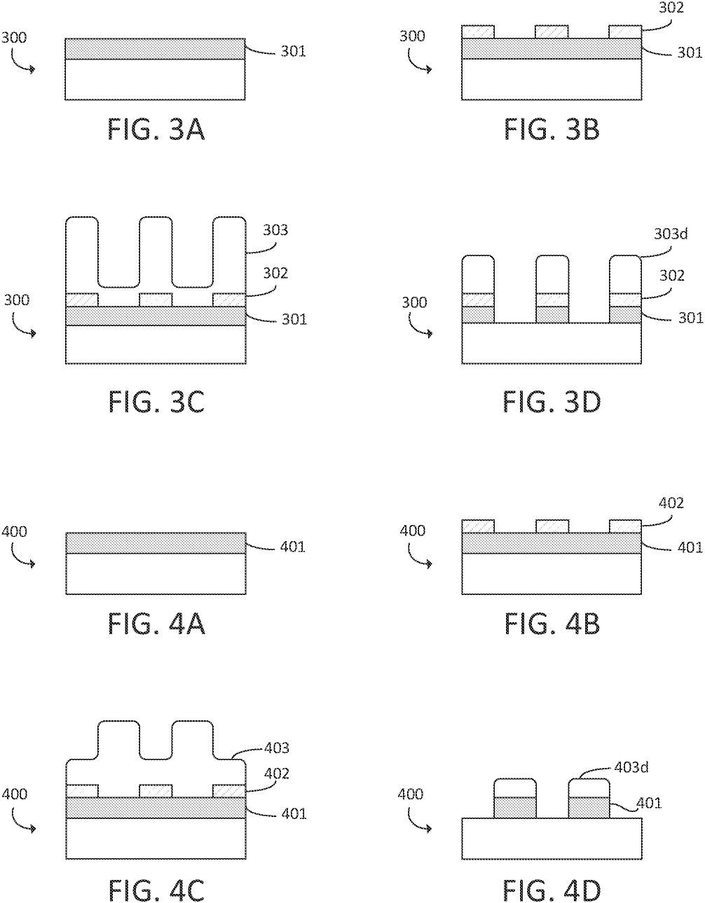

For instance, in cases where the ink includes a plating accelerator, areas of the substrate where ink is present will experience preferential electroplating in comparison to areas of the substrate where ink is absent. Conversely, in cases where the ink includes a plating inhibitor, areas of the substrate where ink is absent will experience preferential electroplating in comparison to areas of the substrate where ink is present. Each of these examples is further described in relation to FIGS. 3A-3D and 4A-4D, below. In either case, some amount (e.g., a non-zero amount) of deposition may occur at both printed and non-printed areas of the substrate. However, the different deposition rates achieved in printed vs. non-printed areas result in the growth of patterned features. The features are positioned in areas that experience greater metal deposition rates. In other words, the term “feature” as used herein is intended to refer to a positive/raised feature, rather than a negative/recessed feature, unless stated otherwise.

After the metal is electroplated through the preferential deposition process, the substrate is transferred to a chemical etching apparatus 256, and in operation 207 the substrate is chemically etched to remove excess plated metal and seed layer. The plated metal may be partially removed in areas where the features are present. The plated metal and seed layer may be substantially or completely removed in areas between the features, since there is relatively less metal in these areas prior to etching (as compared to the areas where the features are present). This etching acts to spatially and electronically isolate the metal features from one another.

The various pieces of processing equipment may be combined in various ways. In one example, a system includes a physical vapor deposition apparatus, an electrohydrodynamic ejection printing apparatus, an electroplating apparatus, and a chemical etching apparatus, with each apparatus being distinct and separate from the others. In another embodiment, one or more of the apparatuses shown in FIG. 2B may be provided in a module of a larger apparatus that performs multiple processes. For example, the physical vapor deposition apparatus may be a separate apparatus, while the liquid-based atmospheric processing apparatuses such as the electrohydrodynamic ejection printing apparatus, electroplating apparatus, and chemical etching apparatus may be provided as modules in a unified processing apparatus. In another example, the physical vapor deposition apparatus and chemical etching apparatus may each be separate, distinct apparatuses, while the electrohydrodynamic ejection printing apparatus and electroplating apparatus are each provided as a module within a larger unified processing apparatus. In another example, the chemical etching apparatus is a separate, distinct apparatus, while the physical vapor deposition apparatus, electrohydrodynamic ejection printing apparatus, and electroplating apparatus are each provided as modules in a larger, unified processing apparatus. In another example, the physical vapor deposition apparatus and the electrohydrodynamic ejection printing apparatus are each provided as modules in a larger, unified processing apparatus, while the electroplating apparatus and chemical etching apparatus are either provided as separate, distinct processing apparatuses, or together as a second unified processing apparatus. In yet other embodiments, one or more of the physical vapor deposition apparatus and/or the electroplating apparatus may be modified to include hardware for performing electrohydrodynamic ejection printing. In cases where an electroplating apparatus is modified to include hardware for performing electrohydrodynamic ejection printing, care should be taken to ensure that the ink used in the electrohydrodynamic ejection printing process is not able to contaminate the electroplating solution. Movable baffles or other containment hardware may be provided. Many configurations of the apparatuses shown in FIG. 2B are possible, and any such combinations are considered to be within the scope of the embodiments herein. The tools so configured can be of a linear, multilevel, carousel, conveyer, cluster, or other general tool design, and the number of modules for each type of process can be substantially more than one (e.g., 10), where the mix of the number of each type of process module operating in parallel is optimized based on the tool’s productivity/output.

FIGS. 3A-3D depict a partially fabricated semiconductor substrate as features are formed thereon according to one embodiment. In the embodiment of FIGS. 3A-3D, the ink used in the electrohydrodynamic ejection printing process includes an electroplating accelerator. As such, the ink in this example is referred to as “accelerator ink.” FIGS. 3A-3D will be explained in the context of the operations and apparatuses described in FIGS. 2A and 2B. FIG. 3A depicts substrate 300 with seed layer 301 thereon. In a particular example, the substrate 300 includes a layer of silicon dioxide over a silicon wafer, though many different substrates and materials may be used. The seed layer 301 includes a conductive material such as copper, tantalum, or a combination thereof. In another example, the seed layer 301 includes nickel. Various materials and combinations of materials may be used for the seed layer. In certain cases where the seed layer 301 includes a combination of materials, the top-most exposed portion of the seed layer is the same metal as the metal structure to be plated (e.g., copper seed for copper lines), however, this need not always be the case. Generally speaking, the exposed surface of the seed layer 301 should be a metal that is electroplatable in an aqueous solution if aqueous plating is being used (e.g., a nickel seed layer could be used to plate a copper line, but not an exposed surface of metals which aren’t generally plateable due to, for example, inhibitive oxidation surface layers, such as W, Ta, Ti etc.). With reference to FIGS. 2A and 2B, the seed layer 301 may be formed in operation 201 in seed layer deposition apparatus 250 (e.g., a physical vapor deposition apparatus or electroless deposition apparatus in some cases). After the seed layer 301 is provided, accelerator ink 302 is printed on seed layer 301, as shown in FIG. 3B. This printing may be accomplished in the electrohydrodynamic ejection printing apparatus 252 in operation 203. The accelerator ink 302 is printed in a pattern that corresponds to the pattern of desired metal features.

After the accelerator ink 302 is printed on the seed layer 301, metal 303 is electroplated on the seed layer 301 and on the accelerator ink 302. This electroplating occurs in electroplating apparatus 254 in operation 205. Although the metal 303 forms over both printed and non-printed areas as shown in FIG. 3C, it grows more quickly, and therefore more extensively, over the areas that are printed with the accelerator ink 302. In effect, the accelerator presence in the accelerator ink 302, together with optional additional plating additives in the electroplating solution (e.g., a suppressor that slows down the relative plating rate of the non-accelerator-printed regions, and an optional leveler) act to promote a greater rate of electroplating in the printed areas vs. the non-printed areas. In this example, the metal 303 preferentially plates 3 times faster in the printed areas vs. the non-printed areas. In many embodiments herein, the metal 303 preferentially plates at least 4 times faster, or at least 10 times faster, or at least 20 times faster in the printed areas vs. the non-printed areas. The relative deposition rates depend on factors such as the concentration of additive deposited by printing, applied voltage or total applied current, temperature, and choice of acid and/or copper concentration and chemical identity of any chosen plating additives (e.g., suppressor and/or leveler) in the plating electrolyte. As a result of the differential deposition rates, the pattern provided by the accelerator ink 302 transfers through to metal 303. After electroplating, the substrate 300 is transferred to a chemical etching apparatus 256, and is subjected to chemical etching in operation 207 to remove a portion of metal 303 and a portion of seed layer 301, as shown in FIG. 3D. Specifically, the substrate 300 is etched to such a degree that both metal 303 and seed layer 301 are completely removed in non-printed areas (e.g., areas where accelerator ink 302 is absent), while still remaining in printed areas (e.g., areas where accelerator ink 302 is present). Reference numeral 303d of FIG. 3D represents the metal features that remain on substrate 300 after chemically etching in operation 207. After this etching operation, the metal features 303d are spatially and electronically isolated from one another.

FIGS. 4A-4D depict a partially fabricated semiconductor substrate as features are formed thereon according to another embodiment. In the embodiment of FIGS. 4A-4D, the ink used in the electrohydrodynamic ejection printing process includes an electroplating inhibitor. As such, the ink in this example is referred to as “inhibitor ink.” FIGS. 4A-4D will be explained in the context of the operations and apparatuses described in FIGS. 2A and 2B. FIG. 4A depicts substrate 400 with seed layer 401 thereon. Seed layer 401 is analogous to seed layer 301 of FIG. 3A. Seed layer 401 may be formed in operation 201 in seed layer deposition apparatus 250. After the seed layer 401 is provided, inhibitor ink 402 is printed on seed layer 401, as shown in FIG. 4B. This printing may be accomplished in electrohydrodynamic ejection printing apparatus 252 in operation 203. The inhibitor ink 402 is printed in a pattern that corresponds to the inverse of the pattern of desired metal features. In other words, the inhibitor ink 402 is provided in areas where the metal features are not desired.

After the inhibitor ink 402 is printed on the seed layer 401, metal 403 is electroplated on the seed layer 401 and on the inhibitor ink 402. This electroplating occurs in electroplating apparatus 254 in operation 205. Although the metal 403 forms over both printed and non-printed areas as shown in FIG. 4C, it grows more quickly, and therefore more extensively, over the areas in which inhibitor ink 402 is absent. In effect, the plating inhibitor present in the inhibitor ink 402, together with additional plating additives in the electroplating solution (e.g., accelerator and an optional suppressor and/or leveler) act to promote a greater rate of electroplating in the non-printed areas vs. the printed areas. In this example, the metal 403 preferentially plates three times faster in the non-printed areas vs. the printed areas. In many embodiments herein, the metal 403 preferentially plates at least 4 times faster, or at least 10 times faster, or at least 20 times faster in the non-printed areas vs. the printed areas. As noted in relation to FIGS. 3A-3D, the relative deposition rates depend on factors such as the concentration of additive deposited by printing, applied voltage or total applied current, temperature, and choice of acid and/or copper concentration and chemical identity of any chosen plating additives (e.g., accelerator, suppressor, and/or leveler) in the plating electrolyte. As a result of the differential deposition rates, the inverse of the pattern provided by inhibitor ink 402 is transferred through to metal 403. After electroplating, the substrate 400 is transferred to chemical etching apparatus 256, and is subjected to chemical etching in operation 207 to remove a portion of metal 403, inhibitor ink 402, and a portion of seed layer 401, as shown in FIG. 4D. Specifically, the substrate 400 is etched to such a degree that metal 403, inhibitor ink 402, and seed layer 401 are completely removed in printed areas (e.g., areas where inhibitor ink 402 is present), while still remaining in non-printed areas (e.g., areas where inhibitor ink 402 is absent). Reference numeral 403d of FIG. 4D represents the metal features that remain on substrate 400 after chemically etching in operation 207. After this etching operation, the metal features 403d are spatially and electronically isolated from one another.

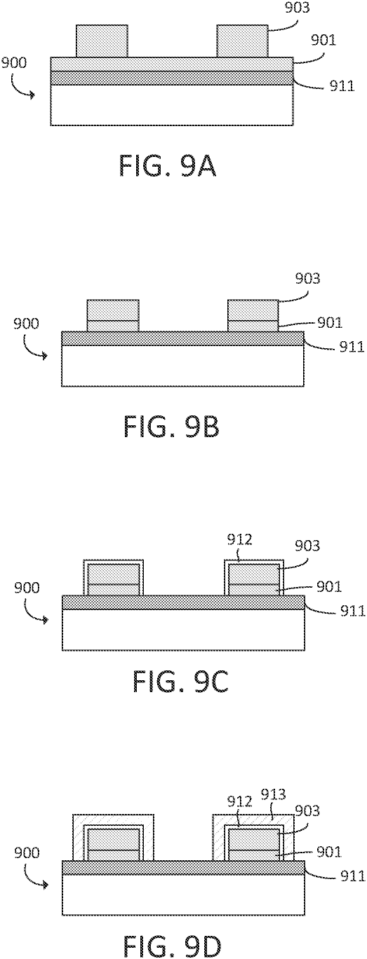

FIGS. 9A-9D illustrate an example process flow that may be used in certain embodiments. The process flow of FIGS. 9A-9D may be combined with those shown in FIGS. 3A-D and 4A-D. In other words, this process flow can be used after preferentially electroplating features with an electrochemically active ink (e.g., an accelerator ink or inhibitor ink). The embodiment shown in FIGS. 9A-9D enables formation of a stack including different types of metal. Such embodiments may be particularly useful in contexts where the feature being formed includes layers of different metals. One example context is the formation of interconnect pillars, which may include, e.g., metal features having diffusion barrier and solder layers thereon. In a particular example, the metal features are copper, the diffusion barrier is nickel, and the solder is tin or tin-silver. Another example context is the formation of relatively wide but thin electrical connection pads. In various embodiments, the stack that is formed may include any combination of copper, nickel, tin, indium, silver, gold, etc.

The substrate 900 begins as shown in FIG. 9A. The substrate 900 includes seed layer 901 positioned over adhesion barrier layer 911. The seed layer 901 is analogous to other seed layers described herein. The adhesion barrier layer 911 may include a material such as tungsten, titanium, tantalum, titanium-tungsten, tantalum-tungsten, etc. Metal 903 is electroplated onto the seed layer, forming raised features. This electroplating may be done using the techniques described herein, for example using electrohydrodynamic ejection printing apparatus 252 to provide an electrochemically active ink on the surface of the substrate, followed by preferential electroplating in electroplating apparatus 254 to form the raised features. While FIGS. 9A-9D do not depict the ink, it is understood that such dried ink may be present between the seed layer 901 and the metal 903, as explained and illustrated in relation to FIGS. 3C and 4C. Further, while FIG. 9A does not show any metal 903 between neighboring features, it is understood that such metal may be present, as shown in FIGS. 3C and 4C.

After the metal 903 is plated onto the seed layer 901, the substrate 900 is transferred to an etching chamber such as chemical etching apparatus 256 of FIG. 2B. Here, the seed layer 901 and metal 903 are etched to remove the seed layer 901 in areas where it is exposed, as shown in FIG. 9B. This etching is analogous to the chemical etching operation 207 of FIG. 2A. The etching process is selective, and is targeted to remove the exposed seed layer 901 while leaving the adhesion barrier layer 911 substantially intact.

Next, the substrate is returned to the electroplating apparatus 254, and a diffusion barrier layer 912 is selectively plated on the metal 903, without substantially depositing on the adhesion barrier layer 911, as shown in FIG. 9C. It is understood that some amount of the diffusion barrier layer 912 may form on the adhesion barrier layer 911, for example at a corner where the seed layer 901/metal 903 contacts the adhesion barrier layer 911. For the purposes of this application, such deposition is not considered to be substantial. Further, it is understood that such deposition only occurs due to the presence of the seed layer 901/metal 903, and that the diffusion barrier layer 912 does not form on the adhesion barrier layer 911 at locations that are removed from the features formed by seed layer 901/metal 903.

One example material for the diffusion barrier layer is nickel, though other materials may be used as desired. Without wishing to be bound by theory or mechanism of action, it is believed that the diffusion barrier layer 912 does not form on the adhesion barrier layer 911 because the adhesion barrier layer 911 becomes oxidized after the seed layer 901 is removed and the adhesion barrier layer 911 is exposed to oxygen/moisture. This exposure to oxygen/moisture may occur as the substrate is transferred between the etching chamber and the electroplating chamber. The oxidized material of the adhesion barrier layer 911 is highly inhibitive to direct nucleation and growth of a plated metal, meaning that metal (e.g., the diffusion barrier layer 912) does not plate on the oxidized material. Further, although the top exposed surface of adhesion barrier layer 911 becomes oxidized, the adhesion barrier layer 911 still provides some electrical connectivity between adjacent features of metal 903, thus enabling further electroplating on metal 903. As such, when the diffusion barrier layer 912 is plated, it selectively deposits on metal 903, without depositing on the adhesion barrier layer 911. The diffusion barrier layer 912 deposits on all exposed sides of metal 903 (as well as exposed portions of seed layer 901, where it is still present below metal 903).

Next, a solder layer 913 is selectively deposited on the diffusion barrier layer 912, without substantially depositing on the adhesion barrier layer 911, as shown in FIG. 9D. This deposition is selective for the same reasons described above in relation to deposition of the diffusion barrier layer 912. The features shown in FIG. 9D may be solder coated pillars or connection pads, for example. The particular structures and materials described in relation to FIGS. 9A-9D are provided for the purpose of illustrating formation of features that include layers of different metals. The embodiments are not intended to be limited to the particular structures or materials described in this section. Various structures and materials may be formed as desired for a particular application, including any combination of the metals described herein.

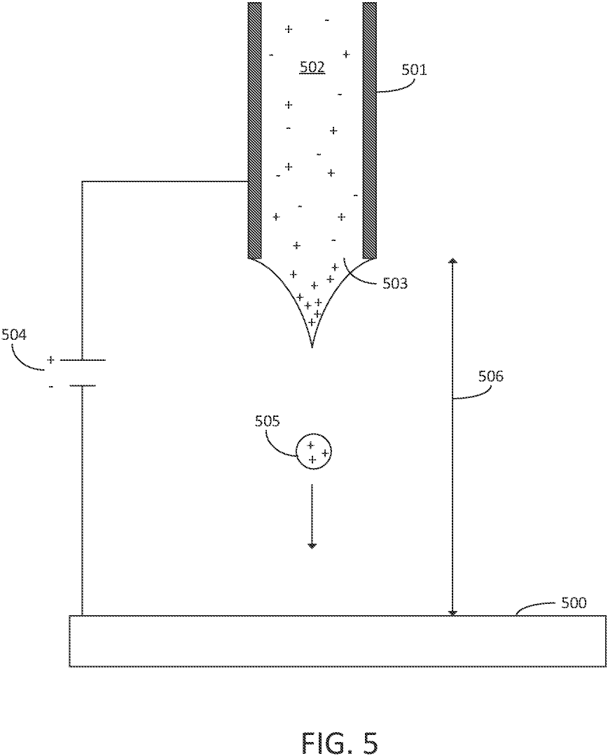

Electrohydrodynamic ejection printing can be used to create extremely fine, small scale patterns that were previously unachievable with alternative printing methods such as inkjet printing. For example, inkjet printing can create features such as dots that have a diameter as small as about 50-100 µm. By comparison, electrohydrodynamic ejection printing can be used to form dots, lines, or other features having dimensions of <0.5 µm. If larger features are desired, electrohydrodynamic ejection printing can be used to form them very precisely, for example at resolutions of <0.5 µm. In other words, electrohydrodynamic ejection printing is useful not only for forming extremely small-scale features, it is also useful for forming somewhat larger features with a high degree of precision. The principles of electrohydrodynamic ejection printing will be explained with reference to FIG. 5.

FIG. 5 illustrates substrate 500 during an electrohydrodynamic ejection printing process. Nozzle 501 is filled with ink 502. Further, nozzle 501 is in fluidic connection with an ink reservoir (not shown) that provides ink 502 into nozzle 501 as needed. Nozzle tip 503 is at the bottom of nozzle 501. Nozzle tip 503 is brought in close proximity to the substrate 500. Upon application of a large potential 504 between nozzle 501 and substrate 500, dipole moment reorientation of solvent molecules within ink 502 with the surface of the substrate 500 results in the creation of a liquid phase surface space charge of opposite sign to that of the substrate surface. This draws ink 502 towards the surface of substrate 500, forming a Taylor cone at nozzle tip 503, from which ink 502 is eventually ejected as ink droplet 505. Ink droplet 505 contains residual charge, and is accelerated toward the surface of substrate 500 in the electric field created by potential 504. Upon impacting the surface of the substrate 500, the charge in ink droplet 505 is neutralized. As a result of this droplet-based fluid flow, current is intermittently flowing in the “circuit” created between the nozzle 501 and the substrate 500. After impacting the substrate 500, solvent in ink droplet 505 dries, leaving behind any non-volatile substances in ink 502. In various embodiments herein, such non-volatile substances may be electroplating additives such as accelerators or inhibitors.

While FIG. 5 shows just a single nozzle, it is understood that an electrohydrodynamic ejection printing process may utilize a large number of independently controllable nozzles provided in a row, column, array, or other configuration. Each of such nozzles can be independently biased to cause them to eject particles, or not, as desired. Further, the nozzles and substrate may move relative to one another such that each nozzle can interact with the substrate at various locations, as desired. In some cases, the nozzles are moveable. In another case, the substrate (e.g., substrate support) is moveable. In yet another case, both the nozzles and the substrate are moveable. While FIG. 5 shows nozzle 501 as a relatively long narrow shaft that protrudes downward, other nozzle designs may also be used. In another embodiment, the nozzle for delivering the ink may be simpler, for example including an orifice in fluidic communication with an ink reservoir. In such an embodiment, the orifice is analogous to the opening at the nozzle tip 503. As used herein, the terms orifice and opening are used interchangeably, unless noted otherwise.

In certain embodiments, the width of the opening at the nozzle tip 503 may be between about 50 to 5000 nm. In many cases, the size of the droplet is about 3 times smaller than the nozzle tip opening. For instance, a nozzle tip opening having a diameter of about 300 nm may be used to form droplets having a diameter of about 100 nm. Generally, the width of the nozzle tip opening should be relatively small in order to print small scale features. For instance, in many cases nozzle widths in the range above may be used to create ink droplets having diameters on the order of about 20-1500 nm. Droplet sizes in this range may be used to form patterns (and eventually plated metal features) at extremely high resolution, for example on the order of <0.5 µm. In certain implementations, a distance 506 between the nozzle tip 503 and the surface of the substrate 500 may be between about 0.05 to 5 mm.

The apparatus may also contain a number of other features not shown in FIG. 5 that support the overall printing process, such as nozzle and/or substrate positioning devices to regulate the 3D position of the nozzle/printing head relative to the substrate. For instance, the apparatus may include hardware for optical location and homing. Such hardware may be configured to detect fiducials on a wafer, thereby allowing for precise alignment between the nozzle/printing head and the substrate, such that printing occurs at desired locations on the substrate relative to the underlying structure on the substrate, a notch and/or other fiducials on the substrate, and/or the edge of the substrate. The apparatus may include hardware for the controlled delivery of printing ink from a bulk storage container to the nozzle head (e.g., pumps, tubes, filters, etc.). The apparatus may include features that support simultaneous independent positioning of multiple nozzles within a multi-nozzle head. A number of individual piezoelectric positioning devices may be provided, each able to move one or more nozzles of a multi-nozzle head assembly relative to each other, thereby enabling a variable line-to-line parallel printing operation spacing. The apparatus may include elements for control of heat removal or addition, and for temperature control of the ink, substrate, or both.

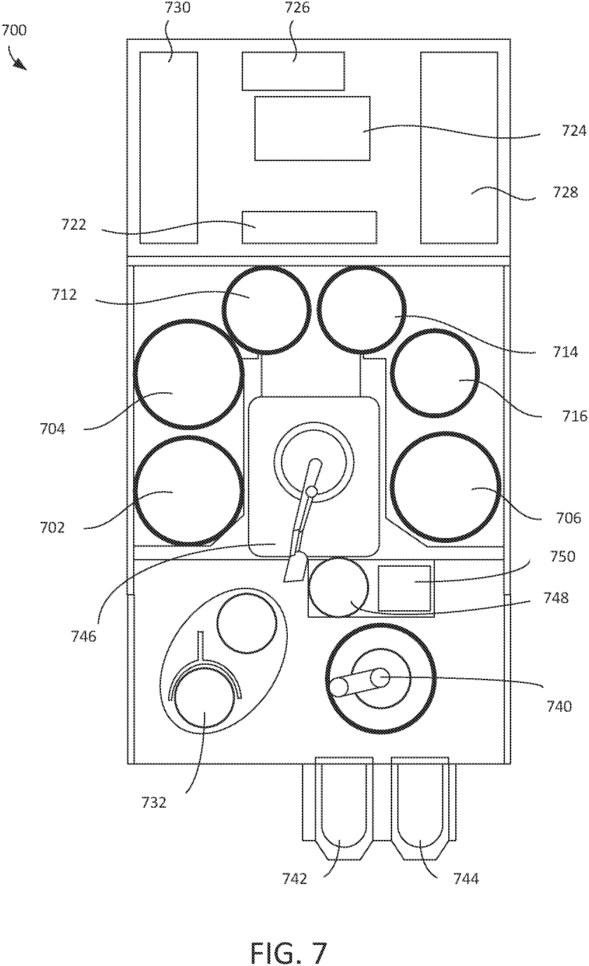

The apparatus may be designed so that the area over the printing head and workpiece are substantially sealed (e.g., forming an environmental chamber), so that the atmospheric environment of the space around the head and/or in the gap between the printing head and the wafer are controlled with respect to temperature and/or gasses present. For example, the environmental chamber may be used to remove a gas (e.g., oxygen or humidity) that is undesired. In these or other examples, one or more gas (e.g., reactive or inert) may be added to the chamber, for example to react with the ink or the substrate or to create an inert atmosphere (e.g., nitrogen, argon). In these or other examples, the apparatus may include hardware to regulate the atmosphere so as to contain a controlled amount of evaporated ink solvent, and/or to perform the printing under vacuum conditions (e.g., which may aid in the evaporation of the solvent). In these or other examples, the apparatus may have one or more front opening unified pods (FOUPs), which are enclosures designed to hold substrates securely and safely in a controlled environment. Substrates may be removed from a FOUP by tools equipped with appropriate load ports and robotic handling systems, as discussed below in relation to FIG. 7, for example. The FOUPs may be used to store incoming and/or outgoing substrates before and/or after they are processed in the apparatus, respectively.

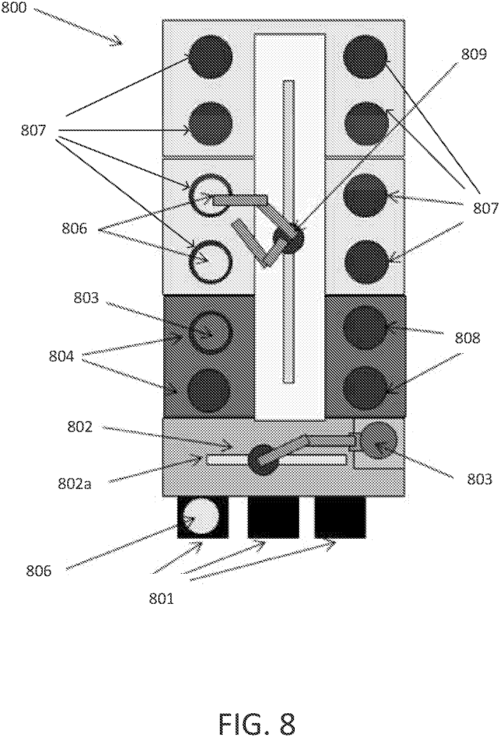

In some embodiments, the apparatus may include two or more modules that operate in parallel with one another. Each module may be configured as described herein, for example to provide electrohydrodynamic ejection printing on a substrate surface. Alternatively or in addition, one or more modules may be configured to perform other functions, as described further below in relation to FIGS. 7 and 8. Such other functions may include but are not limited to pre-treating the substrate prior to printing, rinsing the substrate after printing and before electroplating, drying the substrate after rinsing, and electroplating the substrate. In some examples, a module for pre-treating the substrate prior to printing may operate to remove surface oxides from the wafer. This removal may be accomplished using wet methods in a wet pre-treatment station, or using dry methods in a dry pre-treatment station. Wet methods may involve applying a dilute acid such as H₂SO₄ or a reducing agent such as dimethylamine borane (DMAB) to the substrate surface. Dry methods may involve heating the substrate (e.g., to a temperature between about 100-200° C.) in a reducing atmosphere such as forming gas. In various embodiments, the apparatus may include a system (e.g., a robot handling system) for holding and delivering the wafer between the various modules, as discussed further below in relation to FIGS. 7 and 8.

Other common apparatus features may include fluid condition delivery control apparatus (e.g., heaters/chillers and heat exchangers, level controllers, etc.), and feedback control metrology, for example to regulate nozzle position (e.g., using current feedback with nozzle height being tied to the electrohydrodynamic current) and fluid delivery (e.g., using optical analysis of the liquid film on the substrate). Multi-channel power and/or power switching devices are also envisioned to enable on-off control of an array of electrohydrodynamic ejection printing heads to be individually operated within a larger “printing head.”

One factor that may be controlled during electrohydrodynamic ejection printing is the magnitude of the potential 504 (or relatedly, the current) applied between each of the one or more nozzles 501 and the substrate 500. When the electric field exceeds a particular limit, stress from surface charge repulsion at the apex of the Taylor cone exceeds the surface tension, and the ink droplet 505 is ejected toward the substrate 500. The electric field potential 504 should be below a potential that would result in atomization or poorly controlled spraying of the ink in multiple directions. In certain implementations, the magnitude of the potential 504 applied between the nozzle 501 and the substrate 500 may be between about 0.5-10 kV, or between about 1.5-4 kV. The magnitude of the potential may depend on a number of features including, for example, the identity and properties of the solvent in ink 502, the identity and properties of the electroplating additive in ink 502, the identity and properties of any additional species present in ink 502 (if any), the distance 506 between the nozzle tip 503 and the substrate 500, and the desired size and resolution of the features in the printed pattern.

In various embodiments, the ink and/or ink droplet may have particular properties. In the embodiments herein, the ink includes at least one electroplating additive dissolved in a solvent. In order to ensure that the ink droplet reaches the substrate surface, the ink droplet may have a particular size, and the solvent in the ink may have a particular volatility. In various embodiments, the droplet size may be at least about 20 nm, at least about 50 nm, or at least about 100 nm. In these or other cases, the droplet size may be about 1500 nm or less, about 1000 nm or less, about 400 nm or less, about 200 nm or less, about 100 nm or less, or about 50 nm or less. In some particular examples, the droplet size may be between about 20-1000 nm, or between about 100-400 nm. In these or other embodiments, the solvent present in the ink may have a normal boiling point between about 90-275° C., or between about 100-225° C. In certain cases, the solvent may have a normal boiling point of at least about 95° C., at least about 100° C., at least about 125° C., at least about 150° C., or at least about 175° C. In these or other embodiments, the solvent may have a normal boiling point of about 275° C. or less, for example about 225° C. or less, or about 150° C. or less. In these or other embodiments, the solvent present in the ink may have a vapor pressure at 25° C. of between about 0.05-30 Torr (e.g., between about 6 - 4000 Pa), or between about 0.1-25 Torr (e.g., between about 13-3300 Pa). In many cases, the solvent may have a vapor pressure at 25° C. that is about equal to or less than that of water. At 25° C., water has a vapor pressure of about 23.8 Torr (e.g., about 3175 Pa). As such, in various embodiments the solvent may have a vapor pressure at 25° C. that is equal to or less than about 24 Torr (e.g., less than or equal to about 3200 Pa). While the vapor pressure is considered at 25° C., it is understood that the solvent may be a different temperature during use. Solvents that are more volatile may dry before reaching the substrate surface, at which point the free charge decomposes the solvent in air. Where this is the case, the pattern cannot be effectively printed on the substrate surface. Conversely, solvents that are less volatile may not dry sufficiently quickly once present on the surface of the substrate. Where this is the case, the ink may be smeared and wet out beyond the target dimensions of the desired pattern. In many cases, it is desirable that the droplets completely dry within 100 ms of reaching the substrate surface.

Another consideration regarding the ink is that the solvent should sufficiently solubilize the electroplating additive. In many cases the electroplating additive is a polar organic plating additive. In such cases, the solvent may be polar as well, which may help solubilize the polar organic plating additive. One example of a polar organic plating additive that may be used is the accelerator mercapto-propane sulfonic acid. In some cases, the solvent may have a particular dielectric constant, which may reflect on its ability to solubilize the plating additive. In certain cases, the solvent may have a dielectric constant generally similar to that of water and between about 40 and 90. Generally speaking, the solvent and plating additive should have comparable polarity.

Example solvents that meet the criteria above include water, terpineol, ethylene carbonate, propylene carbonate, dimethylsulfoxide (DMSO), ethylene glycol, polypropylene glycol, and combinations thereof. These example solvents may also be combined with other solvents, provided that the volatility and solubility of electroplating additive within the solvents remain within the guidelines provided above. In many cases, the solvent is organic and nonaqueous, but in some cases water may be used. Examples of co-solvents that can be used to modify the viscosity, dielectric constant, and other properties of the base solvent to create an ink with target performance include dimethyl carbonate, diethyl carbonate, DMSO, and water. Other examples of co-solvents that may be used together include, but are not limited to, diethyl carbonate/propylene carbonate, dimethyl carbonate/propylene carbonate, diethyl carbonate/ethylene carbonate, and dimethyl carbonate/ethylene carbonate.

A further consideration regarding the ink is its viscosity. Inks that are too viscous may be too difficult to process and/or deliver to the printing head, or to draw from the nozzle tip in an appropriate manner, while inks that are insufficiently viscous may smear quickly/easily before drying on the substrate surface. In certain implementations, the ink may have an ambient temperature viscosity (e.g., at 20° C.) of between about 0.7-20 cP, more commonly between about 0.8-3 cP.

The electroplating additive may be provided at a particular concentration within the ink. In some embodiments, the electroplating additive may be provided at a concentration between about 0.01-10 g/L (10-10,000 ppm), or between about 0.1-10 g/L, in some cases between about 0.1-1 g/L (about 100-1000 ppm). In some such embodiments, the electroplating additive may be provided at a concentration that is at least about 0.1 g/L (100 ppm), or at least about 0.15 g/L. (150 ppm), or at least about 0.2 g/L. (200 ppm). The ideal concentration of the electroplating additive for a particular application may depend on factors such as the identity and properties of the electroplating additive, the identity and properties of the solvent, the composition of the electroplating solution that is later used to electroplate the metal features, etc. In various embodiments, the goal is to have the ink supply enough electroplating additive to fully cover and react with the surface it wets (e.g., the seed layer at locations where printed ink is desired), and form at least a monolayer of adsorbed material. It is understood that the monolayer is generally limited to the areas where ink has been printed.

In addition to the electroplating additive and solvent, the ink may include one or more additional species. For example, in some cases the ink may include a wetting agent (e.g., a surfactant). When present, the wetting agent may change the surface tension of the solvent, thereby affecting the size of the ink droplets and the size and shape of the resulting printed pattern and plated metal features. The wetting agent may reduce the contact angle between the ink and the metal surface the ink is printed on (e.g., the seed layer), thereby improving the ink’s wettability. The wetting agent may be a non-electrochemically active compound. In many cases, the wetting agent does not bind to the metal surface (e.g., the seed layer), and so will dissolve away upon rinsing and/or contact with a plating solution. Example surfactants that may act as wetting agents include, for example, sodium lauryl sulfate, polypropylene- or ethyleneglycols or oxides. In these or other cases, the ink may include a salt. When present, the salt may change the vapor pressure, viscosity, and other properties of the ink, thereby affecting the droplet size and the resulting printed pattern and plated metal features. Example salts may include, for example, tetramethyl- or tetraethyl- carbonate, citrate, or hydroxide, and copper sulfate. In cases where the ink includes an accelerator, the ink may be free from suppressors and/or inhibitors. Likewise, in cases where the ink includes an inhibitor, the ink may be free from accelerator. In some cases, for example where a wetting agent is used in combination with an accelerator ink and the wetting agent also happens to behave as a plating suppressor, the ink may include both accelerator and suppressor (e.g., the wetting agent). Electroplating additives such as accelerator, suppressor, and inhibitors, as well as their interaction during an electroplating process, are discussed further below.

The ink may have a particular maximum oxygen concentration when it is delivered to the nozzle of the electrohydrodynamic ejection printing apparatus. In some cases, a degasser may be provided to ensure that concentration of oxygen in the ink is below a maximum target concentration. The degasser may be fluidically connected to the ink reservoir, or between the ink reservoir and the nozzle. In certain embodiments, the maximum oxygen concentration in the ink delivered to the nozzle is about 1 ppm. The oxygen level in the ink can also be controlled by including a species that reacts with and consumes oxygen in the ink itself, such as an organic or inorganic sulfite. One particular example is sodium sulfite. The species that reacts with and consumes oxygen may be provided in the ink at a concentration sufficient to maintain the oxygen concentration at about 1 ppm or less in the ink.

Another factor that can affect the results of the electrohydrodynamic ejection printing process is the temperature at which printing takes place. For example, the temperature of the ink may affect the viscosity of the ink, which can affect the droplet size and resulting printed pattern/plated features. Similarly, the temperature of the substrate can affect how quickly the ink dries. In various cases, the temperature of the ink, the temperature of the nozzle, and/or the temperature of the substrate (or the support on which the substrate is positioned) may be controlled during printing. For instance, the ink and nozzle may be maintained at a temperature between about 100-200° C. during printing. In these or other cases, the temperature of the substrate or substrate support may be controlled during printing. For example, the substrate or substrate support may be maintained at a cooled or heated temperature depending on the particular solvent and ink character. For example, the substrate or substrate support may be maintained at a temperature between about 100-200° C. may be maintain during printing.

In some cases, the ink may be chemically stable such that it can be stored for long periods of time. In other cases, the ink may be less chemically stable. In some such embodiments, the ink may be prepared shortly before use (e.g., about 1 week or less before use, for example about 3 days or less before use, or about 24 hours or less before use) by mixing the relevant components in a relevant solvent at desired concentrations.

The substrate may also have particular properties. For example, in many cases the substrate is a silicon semiconductor wafer. Often, the substrate has a layer of silicon oxide thereon. Further, the substrate typically includes a conductive seed layer, which is exposed at the time that the substrate is provided to the electrohydrodynamic ejection printing apparatus, as shown in FIGS. 3A and 4A. The conductive seed layer is typically metallic, and often includes copper, tantalum, nickel, or a mixture thereof. Other metals may also be used in some cases. The seed layer may have a thickness between about 50-2000Á. After printing in the electrohydrodynamic ejection printing process, the dry ink may have a thickness between about 0.01-0.25 µm. After plating and before etching, the preferentially plated features may have a thickness (e.g., measured as a height) between about 0.25-25 µm. The thickness of the plated metal between the preferentially plated features (e.g., the metal that grew at a relatively slower rate) may have a thickness (e.g., measured as a height) between about 0.05-2 µm. As explained in relation to FIGS. 3D and 4D, chemical etching may be used after electroplating to etch away (i) the unwanted metal between the preferentially plated features, (ii) unwanted seed layer between the preferentially plated features, (iii) unwanted ink, if any, and (iv) a top portion of the metal on the preferentially plated features. After etching, the preferentially plated metal features are spatially and electronically isolated from one another. The isolated features may have a height of between about 0.20-20 µm.

As noted above, the ink typically includes an electroplating additive that acts to promote differential plating rates at printed vs. non-printed areas. In many cases, the additive is an accelerator or an inhibitor. In cases where the ink includes an accelerator, the electroplating solution typically includes a suppressor (and an optional leveler). In cases where the ink includes an inhibitor, the electroplating solution typically includes an accelerator (and an optional leveler). In some cases, however, the electroplating solution may be free (or substantially free) or accelerators, suppressors, inhibitors, and/or levelers. In such cases, the electrolyte may include a solvent (e.g., water), ions of the metal to be plated (e.g., copper ions for plating copper features), and acid.

While not wishing to be bound to any theory or mechanism of action, it is believed that electroplating suppressors such as polyethylene glycol, polyethylene oxide, polypropylene glycol, and polypropylene oxide (either alone or in combination with other electroplating bath additives) are surface-kinetic limiting (or polarizing) compounds that lead to a significant increase in the voltage drop across the substrate-electrolyte interface, especially when present in combination with a surface adsorbing halide (e.g., chloride or bromide). The halide may act as a chemisorbed-bridge between the suppressor molecules and the substrate surface. The suppressor both (1) increases the local polarization of the substrate surface at regions where the suppressor is present relative to regions where the suppressor is absent, and (2) increases the polarization of the substrate surface generally. The increased polarization (local and/or general) corresponds to increased resistivity/impedance and therefore slower plating at a particular applied potential.

It is believed that traditional plating suppressors do not strongly or chemically adsorb onto the substrate surface, and do not become significantly incorporated into the deposited film, though they may slowly degrade over time by electrolysis or chemical decomposition in the electroplating bath. Because traditional plating suppressors do not strongly adsorb onto the substrate surface, these molecules generally do not cause the differential plating rates described herein when provided in an ink. Instead, a traditional plating suppressor provided in an ink would likely be washed away upon rinsing or contact with electroplating solution. Traditional electroplating suppressors are often relatively large molecules, and in many instances they are polymeric in nature (e.g., polyethylene oxide, polypropylene oxide, polyethylene glycol, polypropylene glycol, various co-polymers and mixtures thereof, etc.). Other examples of suppressors include polyethylene and polypropylene oxides with S- and/or N- containing functional groups, block polymers of polyethylene oxide and polypropylene oxides, etc. The suppressors can have linear chain structures or branch structures or both. It is common that suppressor molecules with various molecular weights co-exist in a commercial suppressor solution. Unlike the inhibitors described herein (e.g., which may be used as polarizing agents in an inhibitor ink), suppressor molecules generally do not bind strongly to the surface and can be removed from the surface by rinsing, or will diffuse away from the surface into a plating solution upon contact with the plating solution. Suppressor molecules as used herein therefore are polarizing agents which bind relatively loosely to the surface and are not useful as the principle inhibitor in an inhibitor ink. That said, suppressors may be added to an electrohydrodynamic ejection printing ink for purposes other than causing a differential plating rate. For instance, some suppressors also act as wetting agents/surfactants. Such suppressors may be provided in an electrohydrodynamic ejection printing ink (e.g., an accelerator ink or an inhibitor ink) for the purpose of improving wettability of the ink on a relevant seed layer. Suppressors may also be present in the electroplating solution in which the substrate is plated after printing. Such suppressors may be particularly beneficial in cases where the ink is an accelerator ink.

While not wishing to be bound by any theory or mechanism of action, it is believed that accelerators (either alone or in combination with other bath additives) tend to locally reduce the polarization effect associated with the presence of suppressors, and thereby locally increase the electrodeposition rate. The reduced polarization effect is most pronounced in regions where the adsorbed accelerator is most concentrated (i.e., the polarization is reduced as a function of the local surface concentration of adsorbed accelerator). Example accelerators include, but are not limited to, dimercaptopropane sulfonic acid, dimercaptoethane sulfonic acid, mercaptopropane sulfonic acid, mercaptoethane sulfonic acid, bis-(3-sulfopropyl) disulfide (SPS), and their derivatives. In various embodiments herein, the accelerator includes an alkane chain with at least one mercapto-group and one sulfonic acid group or salt. Although the accelerator may become strongly adsorbed to the substrate surface and generally laterally-surface immobile as a result of the printing process and/or plating reactions, the accelerator is generally not significantly incorporated into the film. Thus, the accelerator remains on the surface as metal is deposited for a significant amount of time, sufficient for a substantial metal film to be deposited.

For the purposes of this disclosure, an inhibitor (which may be present in the ink, for example) is an electrochemically active compound that (i) reacts with or becomes sufficiently strongly adsorbed to the substrate surface (e.g., seed layer) such that it will remain on the surface when the surface is rinsed or contacted with an electroplating solution, and (ii) increases the polarization of the surface (or equivalently, increases the charge transfer resistance, or increases the necessary voltage to drive the same amount of current through the surface during plating).

In certain embodiments, leveler may be present in the ink and/or electroplating solution. While not wishing to be bound by any theory or mechanism of action, it is believed that levelers (either alone or in combination with other bath additives) act as polarizing agents. In some cases the leveler may displace, remove, or drive the accelerator to be incorporated into a growing metal film, thereby counteracting the depolarization effect associated with accelerators.

The leveler may locally increase the polarization/surface resistance of the substrate, thereby slowing the local electrodeposition reaction in regions where the leveler is present. The key attribute of levelers is that the local surface concentration of levelers is determined to some degree by mass transport, and typically the leveler is continuously consumed into the growing plated film or converted to a non-inhibiting byproduct as a result of contact with the surface and/or electroreduction. Because of this consumption/conversion, the leveler is supplied continuously to the surface to maintain a desired concentration of leveler at the surface. Levelers will act principally on surface structures having geometries that protrude away from the surface and are more exposed to the solution environment. This action “smooths” the surface of the electrodeposited layer. It is believed that in many cases the leveler reacts with or is consumed at the substrate surface at a rate that is at or near a diffusion limited rate, and therefore, a continuous supply of leveler is often beneficial in maintaining uniform plating conditions over time. In certain implementations, both the ink and the electroplating solution may be free of leveler (or similarly, leveler may be present but only at trace amounts).

Leveler compounds are generally classified as levelers based on their electrochemical function and impact and do not require specific chemical structure or formulation. However, levelers often contain one or more nitrogen, amine, imide or imidazole, and may also contain sulfur functional groups. Certain levelers include one or more five and six member rings and/or conjugated organic compound derivatives. Nitrogen groups may form part of the ring structure. In amine-containing levelers, the amines may be primary, secondary, tertiary, or quaternary alkyl or aryl amines. Furthermore, the amine may be an aryl amine or a heterocyclic amine. Example amines include, but are not limited to, dialkylamines, trialkylamines, arylalkylamines, triazoles, imidazole, triazole, tetrazole, benzimidazole, benzotriazole, piperidine, morpholines, piperazine, pyridine, oxazole, benzoxazole, pyrimidine, quinoline, and isoquinoline. Imidazole and pyridine may be especially useful. Another example leveler is Janus Green B. Leveler compounds may also include ethoxide groups. For example, the leveler may include a general backbone similar to that found in polyethylene glycol or polyethyelene oxide, with fragments of amine functionally inserted over the chain (e.g., Janus Green B). Example epoxides include, but are not limited to, epihalohydrins such as epichlorohydrin and epibromohydrin, and polyepoxide compounds. Polyepoxide compounds having two or more epoxide moieties joined together by an ether-containing linkage may be especially useful. Some leveler compounds are polymeric, while others are not. Example polymeric leveler compounds include, but are not limited to, polyethylenimine, polyamidoamines, quaternized poly(vinylpyridine), and reaction products of an amine with various oxygen epoxides or sulfides. One example of a non-polymeric leveler and electroplating inhibitive compound is 6-mercapto-hexanol. Similarly, many other organic thiol alcohol and compounds other than thiol-sulphonic group-containing compounds, when adsorbed to the surface, will act as levelers/plating inhibitors. Another example of a suitable leveler is polyvinylpyrrolidone (PVP).

Generally speaking, accelerators increase the plating rate and inhibitors, suppressors, and levelers decrease the plating rate. Because levelers also function to decrease the plating rate, certain levelers may be considered inhibitors for purposes of this application, provided they meet the criteria of an inhibitor. As described above, an inhibitor is a species that becomes bound to the surface of the substrate (e.g., the seed layer) and acts to preferentially retard the plating reaction where the inhibitor is present, as opposed to where it is absent. When an inhibitor ink is used, the local plating inhibition resulting from the inhibitor in the inhibitor ink should continue long enough to create a plating contrast during electroplating (e.g., regions with greater plating where the inhibitor is absent and less plating where the inhibitor is present).

The electrolyte used in the electroplating process may have particular properties. In one example, the ink used in the electrohydrodynamic ejection printing process includes an electroplating accelerator (e.g., accelerator ink). As such, the electrolyte used in the electroplating process may be free of accelerator (or may have only trace amounts of accelerator). This ensures that the accelerator only adsorbs onto the substrate surface at desired locations, e.g., locations where the accelerator ink is printed and where the metal features are desired. In these cases, the electrolyte includes one or more other plating additives such as suppressor and an optional leveler. Example suppressor concentrations may be between 10 to 1000 ppm and example leveler concentrations, when present, may be between about 0.1 to 2 ppm. Further, the electrolyte typically includes copper ions (e.g., from copper sulfate or other source) at a concentration between about 10-60 g/L, an acid (e.g., sulfuric acid) at a concentration of about 5-180 g/L, and halide ion (e.g., chloride, bromide, fluoride, etc.) at a concentration of about 30-80 ppm. The halide ions may act to enhance adsorption of the suppressor molecules on the substrate surface. In this example, current is applied to the substrate during electroplating, causing copper to deposit on both printed and non-printed regions, with preferential (e.g., greater) deposition occurring on the regions printed with the accelerator ink.

In another example, the ink used in the electrohydrodynamic ejection printing process includes an electroplating inhibitor (e.g., inhibitor ink). As such, the electrolyte used in the electroplating process may be free of inhibitors (or may have only trace amounts of inhibitors). This ensures that the inhibitor only adsorbs onto the substrate surface at desired locations, e.g., locations where the inhibitor ink is printed and where the metal features are not desired. In some embodiments, the plating solution used to electroplate the features may contain only an acid (e.g. sulfuric acid at between about 5-180 g/L) and cupric ion (e.g., at between about 10-60 g/L). However, depending on the relative surface adsorption strength between the inhibitor in the inhibitor ink and an accelerator used in a plating bath, one or more additional components such as an accelerator, chloride ion, and suppressor may be present in the plating bath to enhance plating rate contrast. In particular, if the inhibitor is more strongly adsorbed and will not be displaced at the surface by the accelerator, then accelerator can be present in the plating solution and will adsorb to the inhibitor-free regions of the surface. In these cases, the electrolyte can include one or more other plating additive such as accelerator and an optional leveler. Example accelerator concentrations may be between about 10-1000 ppm, and example leveler concentrations, when present, may be between about 0.1-2 ppm. Further, the electrolyte typically includes copper ions (e.g., from copper sulfate or other source) at a concentration between about 10-60 g/L, an acid (e.g., sulfuric acid) at a concentration of about 5-180 g/L, and in various cases halide ion (e.g., chloride, bromide, fluoride, etc.) at a concentration of about 30-80 ppm. In this example, current is applied to the substrate during electroplating, causing copper to deposit on both printed and non-printed regions, with preferential (e.g., greater) deposition occurring on the regions in which the inhibitor ink is absent.

In an alternative embodiment where the accelerator adsorbs onto the substrate surface more weakly than the inhibitor adsorbs onto the substrate surface, after printing the inhibitor onto the surface, accelerator such as mercaptopropane sulphonic acid can be exposed to the entire surface prior to plating. As an example of this embodiment, after printing the surface selectively with inhibitor ink, a solution containing 1 g/L mercaptopropane sulphonic acid (or other accelerator) is sprayed or otherwise provided onto the substrate surface while rotating the surface to expose the entire surface to the accelerator. While not wishing to be bound to any particular model or theory, the accelerator adsorbs onto the inhibitor-free regions of the metal surface, but does not react with or displace the inhibitor where it has been printed. The surface is then sprayed with wafer to rinse it, and then optionally spin dried. This leaves a surface with regions of adsorbed inhibitor from the printing process and regions of adsorbed accelerator from the spraying process. The regions of adsorbed inhibitor correspond to the regions that were printed with inhibitor ink, while the regions of adsorbed accelerator correspond to the inverse of these regions. Subsequent plating of the surface in a plating solution (which may be accelerator-free) leads to high contrast in plating rate between the two regions.

After the substrate is electroplated, it may be subjected to a chemical etching operation to remove excess plated metal, ink, and seed layer, and thereby spatially and electronically isolate the individual metal features as desired. The etching process may involve contacting the substrate with a chemical etchant. The etching process proceeds for a duration sufficient to remove the unwanted materials, but not long enough to fully remove the desired metal features.

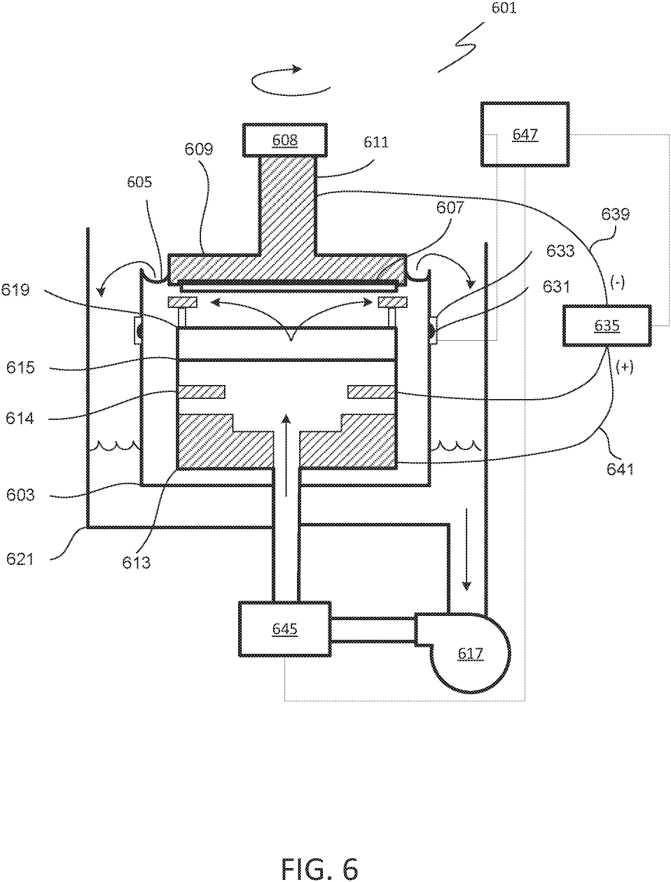

FIG. 6 presents an example of an electroplating cell in which electroplating may occur. Often, an electroplating apparatus includes one or more electroplating cells in which the substrates (e.g., wafers) are processed. Only one electroplating cell is shown in FIG. 6 to preserve clarity. To optimize electroplating and ensure that the electroplating additives are able to function over an extended period of time, the electroplating additives should be prevented from reacting with an anode. Therefore, anodic and cathodic regions of the plating cell are sometimes separated by a membrane so that plating solutions of different composition may be used in each region. Plating solution in the cathodic region is called catholyte; and in the anodic region, anolyte. The electroplating additives may be limited to the catholyte to prevent unwanted reactions with the anode. A number of engineering designs can be used in order to introduce anolyte and catholyte into the plating apparatus.

Referring to FIG. 6, a diagrammatical cross-sectional view of an electroplating apparatus 601 in accordance with one embodiment is shown. The plating bath 603 contains the plating solution (having a composition as provided herein), which is shown at a level 605. The catholyte portion of this vessel is adapted for receiving substrates in a catholyte. A wafer 607 is immersed into the plating solution and is held by, e.g., a “clamshell” substrate holder 609, mounted on a rotatable spindle 611, which allows rotation of clamshell substrate holder 609 together with the wafer 607. A general description of a clamshell-type plating apparatus having aspects suitable for use with this invention is described in detail in U.S. Pat. 6,156,167 issued to Patton et al., and U.S. Pat. 6,800,187 issued to Reid et al.

An anode 613 is disposed below the wafer within the plating bath 603 and is separated from the wafer region by a membrane 615, preferably an ion selective membrane. For example, Nafion™ cationic exchange membrane (CEM) may be used. The region below the anodic membrane is often referred to as an “anode chamber.” The ion-selective anode membrane 615 allows ionic communication between the anodic and cathodic regions of the plating cell, while preventing the particles generated at the anode from entering the proximity of the wafer and contaminating it. The anode membrane is also useful in redistributing current flow during the plating process and thereby improving the plating uniformity. Detailed descriptions of suitable anodic membranes are provided in U.S. Pats. 6,126,798 and 6,569,299 issued to Reid et al. Ion exchange membranes, such as cationic exchange membranes, are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

In some cases, convection and/or diffusion throughout the plating bath may be controlled. A typical way to assist the diffusion is through convection flow of the electroplating solution provided by the pump 617. Additionally, a vibration agitation or sonic agitation member may be used, as well as wafer rotation. For example, a vibration transducer 608 may be attached to the clamshell substrate holder 609. The plating solution is continuously provided to plating bath 603 by the pump 617. Generally, the plating solution flows upwards through an anode membrane 615 and a diffuser plate 619 to the center of wafer 607 and then radially outward and across wafer 607. The plating solution also may be provided into the anodic region of the bath from the side of the plating bath 603. The plating solution then overflows plating bath 603 to an overflow reservoir 621. The plating solution is then filtered (not shown) and returned to pump 617 completing the recirculation of the plating solution. In certain configurations of the plating cell, a distinct electrolyte is circulated through the portion of the plating cell in which the anode is contained while mixing with the main plating solution is prevented using sparingly permeable membranes or ion selective membranes.

A reference electrode 631 is located on the outside of the plating bath 603 in a separate chamber 633, which chamber is replenished by overflow from the main plating bath 603. Alternatively, in some embodiments the reference electrode is positioned as close to the substrate surface as possible, and the reference electrode chamber is connected via a capillary tube or by another method, to the side of the wafer substrate or directly under the wafer substrate. In some of the preferred embodiments, the apparatus further includes contact sense leads that connect to the wafer periphery and which are configured to sense the potential of the metal seed layer at the periphery of the wafer but do not carry any current to the wafer.

A reference electrode 631 is typically employed when electroplating at a controlled potential is desired. The reference electrode 631 may be one of a variety of commonly used types such as mercury/mercury sulfate, silver chloride, saturated calomel, or copper metal. A contact sense lead in direct contact with the wafer 607 may be used in some embodiments, in addition to the reference electrode, for more accurate potential measurement (not shown).

A DC power supply 635 can be used to control current flow to the wafer 607. The power supply 635 has a negative output lead 639 electrically connected to wafer 607 through one or more slip rings, brushes and contacts (not shown). The positive output lead 641 of power supply 635 is electrically connected to an anode 613 located in plating bath 603. The power supply 635, a reference electrode 631, and a contact sense lead (not shown) can be connected to a system controller 647, which allows, among other functions, modulation of current and potential provided to the elements of electroplating cell. For example, the controller may allow electroplating in potential-controlled and current-controlled regimes. The controller may include program instructions specifying current and voltage levels that need to be applied to various elements of the plating cell, as well as times at which these levels need to be changed. When forward current is applied, the power supply 635 biases the wafer 607 to have a negative potential relative to anode 613. This causes an electrical current to flow from anode 613 to the wafer 607, and an electrochemical reduction (e.g. Cu²⁺ + 2 e⁻ = Cu⁰) occurs on the wafer surface (the cathode), which results in the deposition of the electrically conductive layer (e.g. copper) on the surfaces of the wafer. An inert anode 614 may be installed below the wafer 607 within the plating bath 603 and separated from the wafer region by the membrane 615.

The apparatus may also include a heater 645 for maintaining the temperature of the plating solution at a specific level. The plating solution may be used to transfer the heat to the other elements of the plating bath. For example, when a wafer 607 is loaded into the plating bath the heater 645 and the pump 617 may be turned on to circulate the plating solution through the electroplating apparatus 601, until the temperature throughout the apparatus becomes substantially uniform. In one embodiment the heater is connected to the system controller 647. The system controller 647 may be connected to a thermocouple to receive feedback of the plating solution temperature within the electroplating apparatus and determine the need for additional heating.

The controller will typically include one or more memory devices and one or more processors. The processor may include a CPU or computer, analog and/or digital input/output connections, stepper motor controller boards, etc. In certain embodiments, the controller controls all of the activities of the electroplating apparatus. Non-transitory machine-readable media containing instructions for controlling process operations in accordance with the present embodiments may be coupled to the system controller.

Typically, there will be a user interface associated with controller 647. The user interface may include a display screen, graphical software displays of the apparatus and/or process conditions, and user input devices such as pointing devices, keyboards, touch screens, microphones, etc. The computer program code for controlling electroplating processes can be written in any conventional computer readable programming language: for example, assembly language, C, C++, Pascal, Fortran or others. Compiled object code or script is executed by the processor to perform the tasks identified in the program. One example of a plating apparatus that may be used according to the embodiments herein is the Lam Research Sabre tool. Electrodeposition can be performed in components that form a larger electrodeposition apparatus.

FIG. 7 shows a schematic of a top view of an example electrodeposition apparatus. The electrodeposition apparatus 700 can include three separate electroplating modules 702, 704, and 706. The electrodeposition apparatus 700 can also include three separate modules 712, 714, and 716 configured for various process operations. For example, in some embodiments, one or more of modules 712, 714, and 716 may be a spin rinse drying (SRD) module. Such a module may be used to rinse and dry a substrate after an ink is printed thereon. In other embodiments, one or more of the modules 712, 714, and 716 may be post-electrofill modules (PEMs), each configured to perform a function, such as edge bevel removal, backside etching, and acid cleaning of substrates after they have been processed by one of the electroplating modules 702, 704, and 706. In some embodiments, one or more of modules 712, 714, and 716 may be configured to provide a seed layer on the substrate. In these or other embodiments, one or more of modules 712, 714, and 716 may be a pre-treatment module configured to pre-treat the substrate as described herein, for example using wet or dry processing methods to remove an oxide layer from a top surface of a seed layer. In these or other embodiments, one or more of modules 712, 714, and 716 may be an electrohydrodynamic ejection printing module configured to perform the electrohydrodynamic ejection printing process described herein. Such an electrohydrodynamic ejection printing module may have any one or more of the features described in relation to FIG. 5. In these or other embodiments, one or more of modules 712, 714, and 716 may be a chemical etching module configured to chemically etch the substrate after electroplating, as described herein. In certain embodiments, additional modules (not shown) may be provided to perform any of these functions or other functions described herein.

The electrodeposition apparatus 700 includes a central electrodeposition chamber 724. The central electrodeposition chamber 724 is a chamber that holds the chemical solution used as the electroplating solution in the electroplating modules 702, 704, and 706. The electrodeposition apparatus 700 also includes a dosing system 726 that may store and deliver additives for the electroplating solution. A chemical dilution module 722 may store and mix chemicals to be used as an etchant. A filtration and pumping unit 728 may filter the electroplating solution for the central electrodeposition chamber 724 and pump it to the electroplating modules.

A system controller 730 provides electronic and interface controls to operate the electrodeposition apparatus 700. The system controller 730 (which may include one or more physical or logical controllers) controls some or all of the properties of the electroplating apparatus 700.

Signals for monitoring the process may be provided by analog and/or digital input connections of the system controller 730 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

A hand-off tool 740 may select a substrate from a substrate cassette such as the cassette 742 or the cassette 744. The cassettes 742 or 744 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 740 may hold the substrate using a vacuum attachment or some other attaching mechanism.

The hand-off tool 740 may interface with a wafer handling station 732, the cassettes 742 or 744, a transfer station 750, or an aligner 748. From the transfer station 750, a hand-off tool 746 may gain access to the substrate. The transfer station 750 may be a slot or a position from and to which hand-off tools 740 and 746 may pass substrates without going through the aligner 748. In some embodiments, however, to ensure that a substrate is properly aligned on the hand-off tool 746 for precision delivery to an electroplating module, the hand-off tool 746 may align the substrate with an aligner 748. The hand-off tool 746 may also deliver a substrate to one of the electroplating modules 702, 704, or 706 or to one of the three separate modules 712, 714, and 716 configured for various process operations.

An example of a process operation according to the methods described above may proceed as follows: (1) electrodeposit copper or another material onto a substrate in the electroplating module 704; (2) rinse and dry the substrate in SRD in module 712; and, (3) perform edge bevel removal in module 714.

An apparatus configured to allow efficient cycling of substrates through sequential plating, rinsing, drying, and PEM process operations may be useful for implementations for use in a manufacturing environment. To accomplish this, the module 712 can be configured as a spin rinse dryer and an edge bevel removal chamber. With such a module 712, the substrate would only need to be transported between the electroplating module 704 and the module 712 for the copper plating and EBR operations. In some embodiments the methods described herein will be implemented in a system which comprises an electroplating apparatus and a stepper.

An alternative embodiment of an electrodeposition apparatus 800 is schematically illustrated in FIG. 8. In this embodiment, the electrodeposition apparatus 800 has a set of electroplating cells 807, each containing an electroplating bath, in a paired or multiple “duet” configuration. In addition to electroplating per se, the electrodeposition apparatus 800 may perform a variety of other electroplating related processes and sub-steps, such as spin-rinsing, spin-drying, metal and silicon wet etching, electroless deposition, pre-wetting and pre-chemical treating, reducing, annealing, electro-etching and/or electropolishing, photoresist stripping, and surface pre-activation, for example. In some embodiments, electrodeposition apparatus 800 may include one or more modules for accomplishing the various operations described herein, including, for example, deposition of a seed layer, electrohydrodynamic ejection printing, and chemical etching. The electrodeposition apparatus 800 is shown schematically looking top down in FIG. 8, and only a single level or “floor” is revealed in the figure, but it is to be readily understood by one having ordinary skill in the art that such an apparatus, e.g., the Lam Sabre™ 3D tool, can have two or more levels “stacked” on top of each other, each potentially having identical or different types of processing stations.

Referring once again to FIG. 8, the substrates 806 that are to be electroplated are generally fed to the electrodeposition apparatus 800 through a front end loading FOUP 801 and, in this example, are brought from the FOUP to the main substrate processing area of the electrodeposition apparatus 800 via a front-end robot 802 that can retract and move a substrate 806 driven by a spindle 803 in multiple dimensions from one station to another of the accessible stations-----two front-end accessible stations 804 and also two front-end accessible stations 808 are shown in this example. The front-end accessible stations 804 and 808 may include, for example, pre-treatment stations, and spin rinse drying (SRD) stations. Lateral movement from side-to-side of the front-end robot 802 is accomplished utilizing robot track 802a. Each of the substrates 806 may be held by a cup/cone assembly (not shown) driven by a spindle 803 connected to a motor (not shown), and the motor may be attached to a mounting bracket 809. Also shown in this example are the four “duets” of electroplating cells 807, for a total of eight electroplating cells 807. A system controller (not shown) may be coupled to the electrodeposition apparatus 800 to control some or all of the properties of the electrodeposition apparatus 800. The system controller may be programmed or otherwise configured to execute instructions according to processes described earlier herein.

A substrate processing apparatus such as the ones shown in FIGS. 7 and 8 may be modified to include any one or more of the features described in relation to the electrohydrodynamic ejection printing apparatus of FIG. 5.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). In a particular example, a system includes the various apparatus described in relation to FIG. 2B, or any subset thereof. Two or more of the apparatuses may be combined into a unified apparatus, or they may all be distinct from one another. Particular examples are provided above. These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

The techniques described herein enable formation of fine line interconnects, pads, and other metal features at very small scale with a high degree of accuracy and precision (e.g., <0.5 µm). Advantageously, the techniques can be practiced without many of the conventional processes, apparatuses, and materials used in the conventional process flow described in relation to FIGS. 1A and 1B. For example, the techniques herein do not require the use of photoresist, lithography tools, photoresist baking equipment, photoresist curing equipment, photomasks, developing chemicals and tooling, oxygen plasma descum equipment, or photoresist cleaning and stripping equipment. As such, the ownership and processing costs associated with formation of fine line interconnects, pads, and other metal features is substantially reduced. Electrohydrodynamic ejection printing enables the writing of small lines commensurate with current and future market technical demands. For instance, packaging RDL wiring currently involves formation of >5 µm lines and spaces, but is moving toward >2 µm and beyond over the next several years. The techniques described herein provide one route for forming such features at low cost compared to much more expensive and complex conventional process flows.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of depositing metal on a substrate, the method comprising:
a) receiving a substrate comprising a seed layer, wherein the seed layer is conductive and is exposed on a surface of the substrate;
b) printing an ink in a pattern on the seed layer through electrohydrodynamic ejection printing, wherein the ink comprises an electroplating additive dissolved in a solvent, wherein the electroplating additive comprises an accelerator or an inhibitor, and wherein the electroplating additive adsorbs onto the seed layer; and
c) electroplating metal on the substrate through a preferential deposition that provides a first deposition rate at locations where the electroplating additive from the ink is present and a second deposition rate at locations where the electroplating additive from the ink is absent, wherein the first deposition rate is different from the second deposition rate.

2. The method of claim 1, wherein the electroplating additive comprises an accelerator, and wherein the first deposition rate is greater than the second deposition rate such that the metal is preferentially deposited at locations where the accelerator from the ink is present.

3. The method of claim 2, wherein the accelerator comprises an alkane chain with at least one mercapto- and one sulfonic acid group, or an acid-salt.

4. The method of claim 3, wherein the accelerator comprises mercaptopropane sulfonic acid or mercaptoethane sulfonic acid.

5. The method of claim 3, wherein the solvent in the ink comprises at least one material selected from the group consisting of: water, terpineol, ethylene carbonate, propylene carbonate, dimethylsulfoxide (DMSO), ethylene glycol, and propylene glycol.

6. The method of claim 2, further comprising chemically etching the substrate to remove a portion of the metal deposited in (c) and a portion of the seed layer, thereby forming metal features at locations where the accelerator from the ink is present, the metal features being spatially isolated from one another.

7. The method of claim 6, wherein the substrate is electroplated in (c) in an electrolyte comprising:
between about 10-1000 ppm plating suppressor additive,
between about 10-60 g/L copper ions,
between about 5-180 g/L acid, and
between about 30-80 ppm halide ions.

8. The method of claim 7, wherein the electrolyte is either free of accelerator or has only trace amounts of accelerator.

9. The method of claim 1, wherein the electroplating additive comprises an inhibitor, and wherein the first deposition rate is lower than the second deposition rate such that the metal is preferentially deposited at locations where the inhibitor from the ink is absent.

10. The method of claim 9, wherein the inhibitor comprises at least one material selected from the group consisting of: 6-mercaptohexanol and benzotriazole.

11. The method of claim 9, further comprising chemically etching the substrate to remove a portion of the metal deposited in (c), the ink printed in (b), and a portion of the seed layer, thereby forming metal features at locations where the inhibitor from the ink was absent, the metal features being spatially isolated from one another.

12. The method of claim 9, wherein the substrate is electroplated in (c) in electrolyte comprising:
between about 0-1000 ppm accelerator,
between about 10-60 g/L copper ions, and
between about 5-180 g/L acid.

13. The method of claim 12, where the electrolyte is either free of the inhibitor or has only a trace amount of the inhibitor.

14. The method of claim 1, wherein the substrate further comprises an adhesion barrier layer positioned under the seed layer, the method further comprising:
d) chemically etching the substrate to remove a portion of the metal deposited in (c) and a portion of the seed layer, thereby forming metal features, the metal features being spatially isolated from one another; and
e) electroplating a second metal onto the substrate, wherein the second metal selectively deposits on the metal features formed in (d), without substantially forming on the adhesion barrier layer.

15. The method of claim 14, wherein the second metal forms a diffusion barrier layer, the method further comprising:
f) electroplating solder material onto the diffusion barrier layer, wherein the solder material selectively deposits on the diffusion barrier layer formed in (e), without substantially forming on the adhesion barrier layer.

16. The method of claims 1, wherein the electroplating additive in the ink reacts with and chemically binds to the seed layer on the substrate.

17. A system for processing a substrate, the system comprising:
an electrohydrodynamic ejection printing apparatus comprising:
a nozzle having an opening that has a diameter between about 50-5000 nm.
an ink reservoir fluidically connected with the nozzle,
a substrate support for supporting the substrate during printing, and
a power supply configured to apply a potential between the nozzle and the substrate support or between the nozzle and the substrate;
an electroplating apparatus comprising:
a chamber for holding electrolyte,
a substrate holder configured to hold the substrate during electroplating,
an anode, and
a power supply configured to apply potential between the anode and the substrate during electroplating; and
a controller configured to cause:
printing ink in a pattern on the substrate using the electrohydrodynamic ejection printing apparatus, wherein the ink comprises an electroplating additive dissolved in a solvent, the electroplating additive comprising an accelerator or an inhibitor, and
after printing the ink on the substrate, electroplating metal on the substrate using the electroplating apparatus, wherein the electroplating occurs through a preferential deposition that provides a first deposition rate at locations where the electroplating additive from the ink is present and a second deposition rate at locations where the electroplating additive from the ink is absent, and wherein the first deposition rate is different from the second deposition rate.

18. The system of claim 17, further comprising an apparatus configured to deposit a seed layer on the substrate, wherein the controller is configured to cause depositing the seed layer on the substrate before the ink is printed on the substrate.

19. The system of claim 18, further comprising a chemical etching apparatus configured to remove metal from the substrate, wherein the controller is configured to cause removing a portion of the metal electroplated onto the substrate and removing a portion of the seed layer on the substrate.

20. The system claim 17, wherein the electrohydrodynamic ejection printing apparatus and the electroplating apparatus are provided together in a single tool.

21. An ink for electrohydrodynamic ejection printing, the ink comprising:
a) an electroplating additive comprising an accelerator or an inhibitor, wherein the electroplating additive is present at a concentration between about 0.1-10 g/L; and
b) a solvent having:
i. a vapor pressure when at 25° C. that is equal to or less than about 24 Torr, and
ii. a dielectric constant between about 40-90,
wherein the ink has a viscosity between about 0.7-20 cP,
and wherein the electroplating additive is completely dissolved in the solvent.

22. The ink of claim 21, wherein a concentration of oxygen in the ink is about 1 ppm or less.

23. The ink of claim 21, further comprising a species that can react with and consume oxygen, wherein the species that can react with and consume oxygen is present at a concentration sufficient to maintain a concentration of oxygen in the ink at about 1 ppm or less.

24. The ink of claim 23, wherein the species that can react with and consume oxygen comprises a sulfite compound.

25. The ink of claim 21, wherein the electroplating additive comprises the accelerator.

26. The ink of claim 21, wherein the electroplating additive comprises the inhibitor.

27. The ink of claim 26, further comprising halide ions at a concentration between about 30-80 ppm.

28. The ink of claim 21, wherein the solvent comprises at least one material selected from the group consisting of: water, terpineol, ethylene carbonate, propylene carbonate, dimethylsulfoxide (DMSO), ethylene glycol, and propylene glycol.

29. The ink of claim 28, wherein the solvent is organic.

30. The ink of claim 21, wherein the solvent has a natural boiling point between about 95-275° C.

31. The ink of claim 21, wherein the solvent comprises a first co-solvent and a second co-solvent.

32. The ink of claim 21, wherein the ink comprises a wetting agent.

33. The ink of claim 21, wherein the ink comprises a salt.
